(19) United States
(12) Patent Application Publication
(10) Pub. No.: US 2018/0031618 A1
(43) Pub. Date: Feb. 1, 2018

(54) SYSTEM FOR ANALYZING ELECTRICITY CONSUMPTION

(71) Applicants: Yehudah FRIEDLANDER, Har Gilo (IL); Reuven BACHASH, Bat Yam (IL)

(72) Inventors: Yehudah FRIEDLANDER, Har Gilo (IL); Reuven BACHASH, Bat Yam (IL)

(21) Appl. No.: 15/549,729

(22) PCT Filed: Feb. 10, 2016
(86) PCT No.: PCT/IL2016/050161

§ 371 Date: Aug. 9, 2017

(30) Foreign Application Priority Data
Feb. 11, 2015 (IL) 237235

(51) Int. Cl. G01R 21/133; G06F 15/18; G05B 1/01; G06F 19/00

(52) U.S. Cl. CPC G01R 21/133; G06F 19/00; G06F 15/18; G05B 1/01; G05B 2219/32226

(57) ABSTRACT

An apparatus for analyzing electrical consumption measurements, including: a transferring component for receiving sampled electricity consumption data of at least two phases of power supplied to a machine from at least two sensors, and transferring the data to an application server; an application server for receiving the sampled values and analyzing the sampled values for the at least two phases, thereby obtaining information related to a status of the machine or to a type of manufactured item.

### TECHNICAL FIELD

The present disclosure relates to electricity consumption in general, and to a system and method for improving maintenance, enhancing efficiency and monitoring in production floors, in particular.

### BACKGROUND

Operating a shop floor or a production floor is complex and expensive, and requires a lot of resources, including utilities and in particular electrical power, raw materials and human labor. Thus, a person or an organization operating a production floor may wish to reduce expenses, and especially the ones mentioned above in order to maintain profitability of the production floor. Although the term production floor is often used to describe a manufacturing facility, it will be appreciated that in the context of the disclosure the term may be used for any environment with one or more electrical machines, such as a clean room, a hospital, an examination facility, or the like.

Since an important part of the costs relates to energy and in particular electrical consumption, monitoring and reducing the total electrical consumption in general, and per manufactured unit in particular, may be beneficial.

Maintaining the machinery in healthy state helps avoid unexpected failures, and may also assist in improving utilization of the machines and the available manpower, thus avoiding idle time of the equipment and the personnel, missed deadlines, and other problems.

Higher than necessary electrical consumption may be due to a multiplicity of reasons. One such reason is improper maintenance of the device, including insufficient ongoing preventive maintenance, as well as not fully fixing failures and problems; working under suboptimal conditions such as too high or too low temperature or humidity, supplying insufficient, improper or defective raw materials, or the like. Further problems may be caused by non-professional or inefficient personnel operating the machines or other problems. Further causes of reduced profits may even be due to false reporting by personnel.

There is thus a need in the art for a system and method for monitoring and increasing efficiency and productivity in production floors, or by other electricity consumers.

### BRIEF SUMMARY

One exemplary embodiment of the disclosed subject matter is an apparatus for analyzing electricity consumption, comprising: a transferring component for receiving sampled electricity consumption data of two or more phases of power supplied to a machine from two or more sensors, and transferring the data to an application server; an application server for receiving the sampled values and analyzing the sampled values for the at least two phases, thereby obtaining information related to a status of the machine or to a type of manufactured item. Within the apparatus, the transferring component optionally comprises a hub. Within the apparatus, the transferring component optionally comprises a router. Within the apparatus, the transferring component optionally receives the sampled data using a landline or wireless communication, and optionally transmits the sampled data using a landline or wireless communication. Within the apparatus, the application server optionally comprises a logic module for analyzing the sampled values. Within the apparatus, the logic module optionally comprises a comparison engine adapted to compare data sampled by at least two sensors or results of calculations based upon the data to predetermined patterns, predetermined thresholds or calculated values. Within the apparatus, the comparison engine is optionally further adapted to identify a mismatch. Within the apparatus, the comparison engine is optionally further adapted to identify a match thus identifying the machine operational state or the type of manufactured items. Within the apparatus, the logic module optionally comprises a learning module for determining the predetermined patterns or predetermined thresholds. Within the apparatus, the application server optionally comprises an alert and recommendation engine for issuing an alert or a recommendation related to maintenance or operation of the machine or the environment. Within the apparatus, the alert is optionally selected from the group consisting of: a failure in a machine; a machine does not receive proper material supply; improper operation of the machine; improper infrastructure such as power supply; a recommendation for checking for loose or unstable electric contact; setup has not been performed properly; and improper environmental conditions. Within the apparatus, the recommendation is selected from the group consisting of: a recommendation for a maintenance operation of the machine; a recommendation for a part of the machine that needs replacement or fixing; a recommendation for a tool of the machine that needs replacement or fixing; a recommendation for stricter than usual quality assurance of the manufactured item; a recommendation for checking and fixing the material supply to the machine; a recommendation for checking or fixing the operation of the machine; a recommendation for checking or fixing infrastructure such as power supply or environmental conditions of the machine; a recommendation for checking for loose or unstable electric contact; a recommendation for notifying maintenance people, a recommendation for updating work plans, a recommendation for directing work to another machine; and a recommendation for replacing equipment. Within the apparatus, the application server optionally comprises a control and monitoring module for monitoring electric supply and operation of the apparatus.

Another exemplary embodiment of the disclosed subject matter is a method for analyzing electricity consumption, comprising: receiving electricity consumption data from two or more sensors for correspondingly associated with two or more phases of power supplied to a machine; and analyzing the sampled values for the phases, thereby obtaining information related to a status of the machine or to a type of manufactured item. Within the method, analyzing the sampled values comprises comparing the data sampled by the sensors to predetermined patterns or predetermined thresholds, and identifying a mismatch. The method may further comprise determining the predetermined patterns or predetermined thresholds. The method may further comprise comparing the sampled values or results of calculations based upon the data to predetermined patterns, predetermined thresholds or calculated values for identifying a known machine operational state or type of manufactured item. The method may further comprise issuing an alert or a recommendation related to maintenance or operation of the machine or the environment. Within the method, the recommendation is optionally selected from the group consisting of: a recommendation for a maintenance operation of the machine; a recommendation for a part of the machine that needs replacement or fixing; a recommendation for a tool of the machine that needs replacement or fixing; a recommendation for stricter quality assurance of a manufactured item; a recommendation for checking and fixing the material supply to the machine; a recommendation for checking or fixing the operation of the machine; a recommendation for checking or fixing infrastructure such as power supply or environmental conditions of the machine; a recommendation for checking for loose or unstable electric contact; a recommendation for notifying maintenance people, a recommendation for updating work plans, a recommendation for directing work to another machine; and a recommendation for replacing equipment.

Yet another exemplary embodiment of the disclosed subject matter is a computer program product comprising a computer readable storage medium retaining program instructions, which program instructions when read by a processor, cause the processor to perform a method comprising: receiving electricity consumption data from two or more sensors for correspondingly associated with two or more phases of power supplied to a machine; and analyzing the sampled values for the at least two phases, thereby obtaining information related to a status of the machine or to a type of manufactured item.

### THE BRIEF DESCRIPTION OF THE SEVERAL VIEWS OF THE DRAWINGS

The present disclosed subject matter will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIG. 1 shows a high-level schematic block diagram of a system, in accordance with some exemplary embodiments of the subject matter;

FIG. 2 shows graphs of sampled current consumption of three phases connected to a machine, in accordance with some exemplary embodiments of the subject matter;

FIG. 3 shows a detailed block diagram of a system, in accordance with some exemplary embodiments of the subject matter;

FIG. 4 shows a block diagram of the application server logic module, in accordance with some exemplary embodiments of the subject matter; and

FIG. 5 shows a flowchart diagram of a method for analyzing electricity consumption, in accordance with some exemplary embodiments of the disclosed subject matter.

### DETAILED DESCRIPTION

The term machine relates to any device comprising one or more parts, components or modules, is operative to perform an action and which receives electrical supply.

The term sensor relates to a device for sensing one or more characteristics of a power supply line or environment, such as characteristics including electric current. In some embodiments the sensor may convert measured analog values to a digital signal.

The term electricity consumption may refer to current, power, electric energy, or any other measureable size, measured in any relevant unit. It will however be appreciated that the disclosure below may also refer to other types of energy and in particular to measuring energy consumption, analyzing the measurements and improving performance of one or more machines environments, operations, or the like.

One technical problem dealt with by the disclosed subject matter is the need to assess the operational state of a machine or another electricity consuming device. It may be easy to determine whether the machine is on or off, but a machine may also be in a working state or in any of a number of partly operative states. For example, the machine may be in standby mode or in idle mode in which it is on but not providing the expected productivity due to lack or insufficient material supply or low quality of raw material, improper maintenance such as cleaning or calibration, total failure or improper functioning of one or more modules, improper electrical supply, improper or suboptimal environmental conditions, unprofessional operation, or the like.

Yet another technical problem dealt with by the disclosed subject matter relates to assessing professionalism and productivity of personnel, for example by assessing whether the reported production of the machine is equal to the actual production, or assessing whether the actual production is in line with the raw materials provided. In another example problems with employees may be detected, such as the machine is operating but is not manufacturing items because the operator is not doing his or her job, a part of the machine has broken since the worker put too much pressure on it to meet the deadline or the requirements, or the like.

Yet another technical problem dealt with by the disclosed subject matter relates to assessing equipment productivity based on division to departments, sections, machine types, or the like, thus obtaining comparative measures.

Yet another technical problem dealt with by the disclosed subject matter relates to the abundance of information available to operators or owners of a production floor, including supplied utilities reports, machine operation reports, raw material and manufactured items reports, employee hour reports and others. However, lacking specific information that may be used for assessing operative states, or lacking the option to organize and coordinate the information, prevents drawing concrete useful conclusion for improving the productivity and efficiency of a production floor.

One technical solution comprises measurement of the electric supply to each machine, wherein the measurement may be done by sensor such as a current transformer connected to each phase of each machine. Thus, if a machine receives a three-phase electrical supply, the electricity consumed by each phase may be measured separately. The measurements may be sampled and converted into digital values. The sampled measurements may be transferred to a hub which may receive information from a multiplicity of machines, and from the hub to an application server, possibly via a router.

On a preparation stage, also referred to as a training stage, a pattern of the current consumption of each phase of each machine during one or more operation cycles is determined. The patterns may be analyzed, separately or in combination while synchronizing two or more phases, and characteristics of the machine operation may be determined. For example, a basic operation cycle may be determined, indicating the production cycle of the machine. A peak in the consumption of any one or more phases may indicate a stage in the operation of any of the machine modules, while a lower section may indicate an idle or recess time of the module. The current levels during the different phases may be indicated.

In some embodiments, threshold values or allowed ranges may be determined for the current during a certain time slot of the operation cycle in one or more phases for example two or more phases, for any mathematical or another result obtained upon the measurements, or the like, such that if the measured value or the calculated result exceeds or drops below the threshold, or is outside the range, an alert may be issued.

In addition, factory data related to the machines or parts thereof may be obtained as well, and optionally combined with the sampled data, for example determining a known and acceptable deviation between the factory data and the measurements or the results of calculations applied to the measurements as taken during proper operation.

Then in runtime, the same factors may be also measured and optionally sampled, transferred to a hub and a router and analyzed by a computing platform such as the application server. The values may then be matched against the patterns determined during the training stage. In some embodiments, the received samples may be synchronized with the determined patterns, for example by matching the times at which the peak sampled values occurred, with the times at which the peaks occurred in the patterns determined during training, and similarly for the lowest values.

The sampled values may then be analyzed against the determined patterns. During analysis, machine operational state may be identified, such as “working”, “off”, “idle”, “standby”, or the like. Additionally or alternatively, current patterns associated with one or more types of manufactured items can be identified, such that it may be determined whether a given signal is close enough to any of the patterns associated with known item types, or the machine was used for manufacturing an unknown item type. This is relevant, for example, to CNC machines which may be adapted to manufacture various types of items, each associated with a specific current consumption pattern for each phase or a calculation applied thereto.

The analysis results may be used for drawing conclusions and issuing recommendations or fire alerts regarding the machines, their operation and health, the environment, the operators, or other aspects of the production floor. The patterns may be determined phase-wise, according to a phase combination, or based upon a calculation applied to the measured values.

The sampled values may also be stored and analyzed on a long-term basis for discovering trends and issuing corresponding recommendations, such as increasing the frequency of maintenance operation, or the like.

One technical effect of the disclosure relates to drawing conclusions and issuing recommendations related to on-going maintenance and operation of production floor. By analyzing the consumption of electricity or other types of energy, various problems and trends may be discovered, such as inoperative or not fully operative machines or modules thereof, problems with the material supply to a machine, improper operation by an operator, mismatch in manufactured quantities vs. reports, problems with utilities supply, or the like.

Another technical effect of the disclosure relates to identifying problems quickly so that measurements may be taken, such as notifying maintenance people, and/or updating work plans for the production floor, or directing work to other machines in order to meet deadlines.

Another technical effect of the disclosure relates to the ease of deployment and maintenance of the system, and to its safety, achieved by installing the sensors directly or in close proximity to the electrical board or panel, and elimination of excess wiring between the sensors and the other components of the system. The system may have low power consumption and low foot print, thus eliminating overhead and additional expenses.

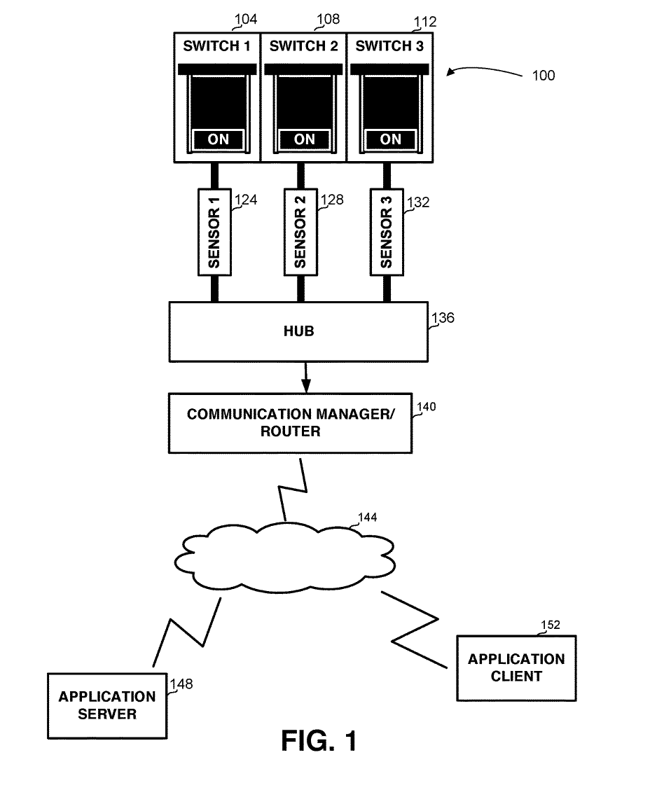

Referring now to FIG. 1, showing a schematic illustration of the components of a system in accordance with the disclosure, and connections therebetween.

An electrical board 100 or panel comprises a multiplicity of switches such as switch 1 (104), switch 2 (108), and switch 3 (112). In some embodiments, such three switches are connected to the three phases providing electricity to one or more machines.

A sensor such as sensor 1 (124) is connected to one such switch, such as switch 1 (104), and similarly for sensor 2 (128) connected to switch 2 (108) and sensor 3 (132) connected to switch 3 (112). Each sensor may measure the current flow through the corresponding switch. The sensor may be implemented as any current transformer, such as a current transformer available from EKM metering of Santa Cruz, Calif., US.

Sensor 124 (as well as the other sensors) comprises measuring components, analog to digital (ADC) converter and one or more communication modules. Sensor 124 transmits the sampled values to a hub 136, optionally through landline, and using any appropriate protocol, such as RS485.

Hub 136 receives samples from a multiplicity of sensors such as sensor 1 (124) and additional sensors. The hub then transmits the data to communication manager or router 140, referred to as router 140, for example using wired or wireless communication channel such as Wi-Fi, Local Area Network (LAN), or others, and using any appropriate protocol such as Zigbee, which is characterized in low power consumption and high bit rate.

Router 140 may receive data from one or more hubs 136 and may transfer the data over medium 144 such as the Internet using wired or wireless communication. The data may be transferred to a central repository, such as application server 148.

In some embodiments, hub 136 and router 140 may be implemented as a unified transferring component for receiving the sampled values from one or more sensors and routing them to application server 148.

Application server 148 may be executed by any general purpose computer, may store the data on an associated storage device, which may be collocated with the computer or remote. Application server 148 may process the incoming data, analyze it and issue reports, alerts or recommendations. The output of application server 148 may be accessed by one or more application clients 152 executed by other computing platforms, such as desktop computers, mobile devices such as mobile phones, laptops, tablet computers or the like. Application client 152 may be used by installing a dedicated application, by using web access to application server 148, or the like.

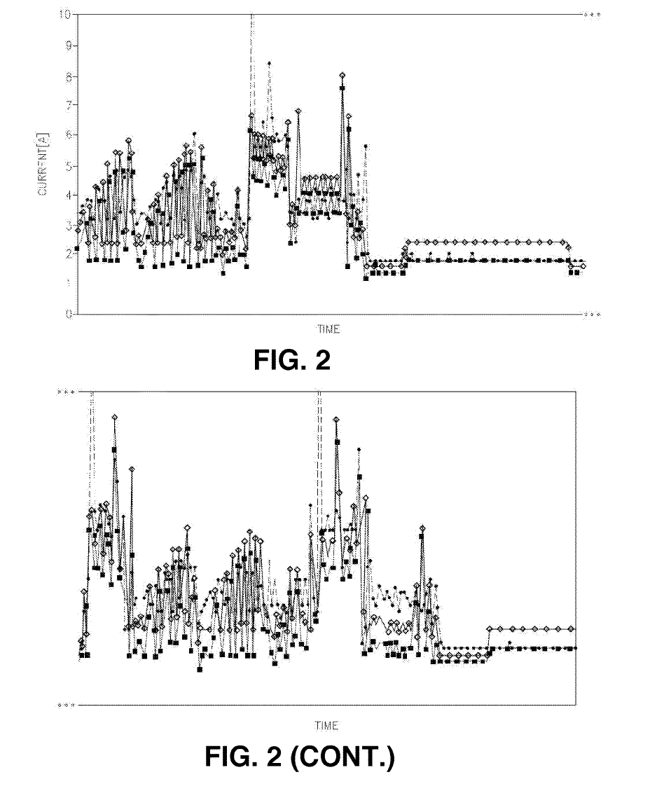

Referring now to FIG. 2, showing exemplary graphs of current consumption by three phases of a CNC machine. First graph 204 relates to a first phase, second graph 208 relates to a second phase and third graph 212 relates to a third phase, wherein all phases supply electricity to the machine.

A repeating pattern, shown on time slots T1 (shown partially) followed by idle or preparation time T1′, and T2 followed by idle or preparation time T2′ (shown partially), is noticeable. If the pattern is noted on a time period in which the machine is known to function properly, this pattern may be used as reference for future analysis.

The pattern may be realized using any pattern recognition algorithm, determined manually, or a combination thereof.

It will be appreciated that in order to overcome small variations which may exist between the cycles, average values per point in time per phase may be determined over a multiplicity of cycles. An acceptable deviation may also be defined, which may be global for the machine, per phase, per point in time, or the like.

During runtime, it may be determined whether in “on” state, the current samples match the pattern of T1 or T2. If there is a match, it may be determined that the manufactured items are of the same type as the items upon which the shown graphs were sampled. Otherwise, if there is no match, it may be determined that an unknown type of item is manufactured. The new type and the associated pattern may then be introduced to the system and recognized in future sessions.

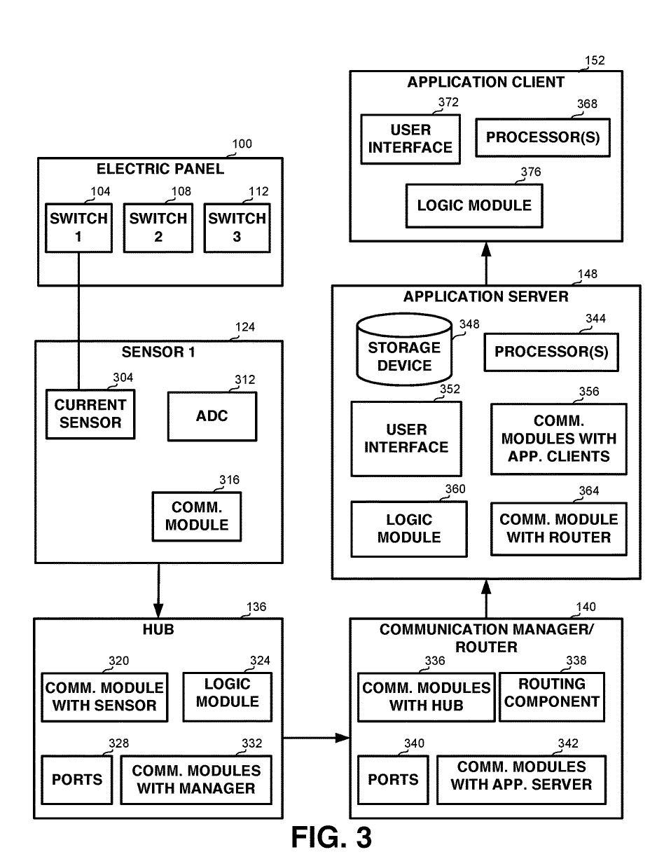

Referring now to FIG. 3, showing a detailed block diagram of the components in an exemplary system in accordance with the disclosure.

Electric board or panel 100 and the switches are as detailed in association with FIG. 1 above.

Sensor 1 (124) may comprise a current sensor 304. In some typical environments, current sensor 304 may measure current in the range of 0-100 A.

Sensor 1 (124) may comprise ADC 312 for converting the continuously sensed current or other measurement into digital signals. The sampling rate may vary, for example, between 0.1 Hz and 200 Hz.

Sensor 1 (124) may comprise communication module 316 for communicating with hub 136. Communication may go through landline and may use an appropriate protocol such as RS485 protocol.

According to the implementation, sensor 1(124) may also comprise a memory unit (not shown).

Hub 136 may comprise a corresponding communication module 320 for communicating with Sensor 1 (124), such as a component implementing the RS485 protocol.

Hub 136 may further comprise logic module 324 for collecting and arranging the data, ports 328 for transmitting the data, and one or more communication modules 332 for communicating with router 140.

In some embodiments, communication modules 332 may comprise RS-232 implementation component, component for serial communication, Zigbee implementation component, Wi-Fi module, or any other alternative or additional communication modules for wired or wireless communication with router 140.

Hub 136 may also comprise one or more memory devices, or one or more microcontrollers.

In an exemplary embodiment, hub 136 may connect to sensor 124 using landline with the RS485 protocol, and to the router using wireless communication in Zigbee protocol in frequency of 2.4 KHz, in accordance with IEEE802.15.4 standard. Such arrangement provides for minimal wiring while collecting data related to a multiplicity of machines.

In this embodiment, hub 136 may receive the effective current from each of up to about 80 sensors every 0.4-60 seconds, and may transmit the data immediately to router 140.

Router 140 may receive a multiplicity of data streams from one or more hubs, and may transmit them to a central repository.

Router 140 may comprise routing component 338 such as standard router Linux OpenWrt for performing the actual routing of the received data.

In some embodiments, router 140 may comprise RS-232 implementation component. Router 140 may comprise TCP/IP implementation component for communicating with application server 148.

In an exemplary embodiment router 140 may comprise communication modules 336 to connect to hub 136 using wired or wireless communication, such as ports 340, Wi-Fi, LAN, or the like, for example using the Zigbee protocol in frequency of 2.4 KHz, in accordance with IEEE802.15.4 standard. In some embodiments router 140 may comprise communication modules with application server 342, and may transmit the information to application server 148 using wired or wireless communication TCP/IP. One router may manage about fifteen or more hubs in one Zigbee channel, and significantly more in Wi-Fi channel.

Application server 148 may comprise processor 344. Processor 344 may be a Central Processing Unit (CPU), a microprocessor, an electronic circuit, an Integrated Circuit (IC) or the like. Processor 344 may be utilized to perform computations required by application server 148 or any of it subcomponents.

Application server 148 may comprise storage device 348. Storage device 348 may be a hard disk drive, a Flash disk, a Random Access Memory (RAM), a memory chip, or the like. In some exemplary embodiments, storage device 348 may retain program code operative to cause processor 344 to perform acts associated with any of the subcomponents of application server 148. Storage device 348 may store data received from a multiplicity of switches as sampled by a multiplicity of sensors and received through one or more hubs or one or more routers. Storage device 348 may also store information about machine operational state, operator reports, or other information related to a production floor.

Storage device 348 may also store previously collected data, patterns or calculation results related to one or more switches or machines, determined thresholds, manufacturer data related to machines, historical data related to the equipment or the production floor, or the like.

Application server 148 may comprise user interface 352 for receiving data from a user or providing data to a user, and communication module 356 for communicating with one or more application clients 152. In some embodiments, application server 148 can also be used as application client 152, in which case such communication may not be required.

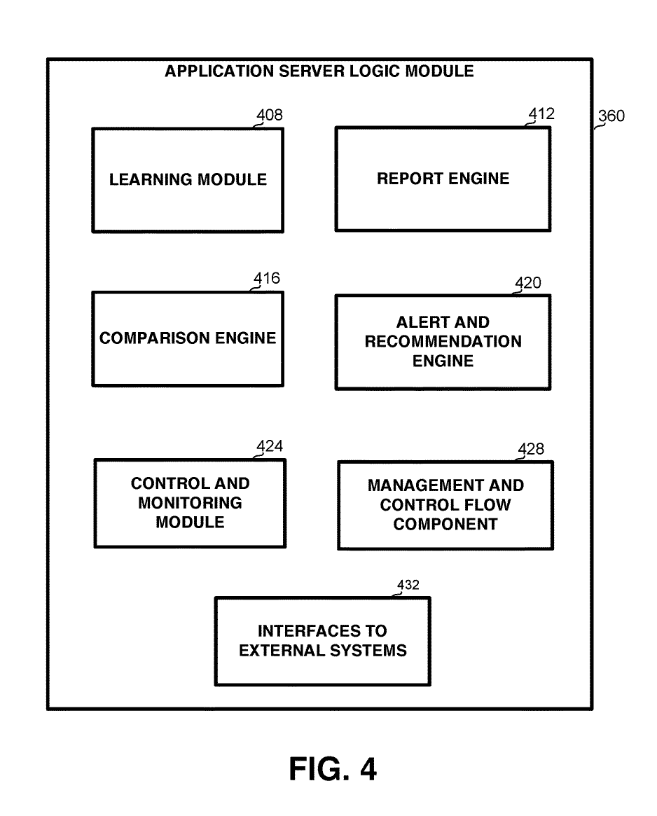

Application server 148 may comprise logic module 360 for analyzing the received data or calculation results, optionally comparing sampled values or calculation results to predetermined patterns to determine the machine operational state or type of manufactured item, comparing sampled values to the stored data such as stored patterns, comparing values to thresholds, or the like. Logic module 360 is further detailed in association with FIG. 4 below.

Application server 148 may comprise a communication module 364, such as a TCP/IP implementing component for communicating with router 140.

Application client 152 may be implemented as any computing platform and may also comprise a processor 368 as detailed above in association with processor 344, and optionally a storage device.

Application client 152 may also comprise user interface 372 for presenting data to a user or receiving input such as queries from a user.

Application client 152 may also comprise logic module 376 for performing further requests by the user on data received from application server 148. Alternatively, application client 152 may be implemented as a web service such that all analysis and computations are performed on application server 148 and are merely displayed to the user using a web browser.

It will be appreciated that application server 148 and application client 152 may comprise a multiplicity of other components and modules, required for their normal operation and not only to the current disclosure.

Referring now to FIG. 4, showing a detailed exemplary implementation of logic module 360 of application server 148.

Application server 148, in addition to supporting all standard requirements of any application server, may comprise within logic module 360 learning module 408 for determining predetermined patterns or thresholds based on previously received data comprising measured and sampled values or calculation results. For example, learning module 408 may be adapted for identifying the current consumption or other signals during various operational states of a machine, such as when active or idle, during different parts of its operation cycle, or the like. Learning module 408 may identify patterns within the data, and may do so for every phase of the current separately, or in combination, for example identifying that after the current consumption of a first phase reaches a peak, the second phase is idle, after which the third phase reaches a peak. As a specific example, area 216 of FIG. 2 in which all phases consume very little electricity may indicate a standby state, which occurs between the manufacturing cycles of two items. For example, the standby period may be characterized as a state in which each phase consumes between 1 A and 2 A, and the difference between the upper and lower values does not exceed 0.8 A. In an Off state all phases consume zero current. In some embodiments, if a machine is not in an Off state, idle state or standby state, it may be assumed that the machine is working.

The standby duration depends on the product. For example, when manufacturing certain items duration of up to 60 seconds may be reasonable while a longer duration may indicate that the machine is turned on but is not manufacturing, which is inefficient. The standby times may be accumulated and presented to a person in charge.

In another example, an idle state of the machine in which the machine parts are moving but no output is manufactured since raw material is not supplied, may be characterized by each phase consuming between 2 A and 3 A, with the difference between the upper and lower values not exceeding 0.9 A. If this state continues for at least 60 seconds, it may be accumulated and reported as well.

Learning module 408 may also be operative in determining threshold values for measured or computed values, which an alert should be issued when exceeded in various situations.

It will be appreciated that learning module 408 may operate automatically by applying computerized algorithms, such as artificial intelligence algorithms. Alternatively, learning module 408 may receive input from a user, for example indications of cycle parts associated with a particular module of a machine. In yet another alternative, a hybrid approach may be used, in which an application may suggest recognized patterns, thresholds, or the like, and a user may accept, reject, add or change the suggestions. The process may also be iterative.

Logic module 360 may comprise report engine 412 for generating reports related to the ongoing usage of the machine, its operational states, types and quantities of manufactured parts, or the like. Report engine 412 may also create diagrams, tables, or other representations of the data.

Logic module 360 may comprise comparison engine 416, adapted to compare received samples or information to data associated with existing equipment. The data may comprise manufacturer data, previous measures, past performance of the machine under similar conditions, such as load, season, environmental conditions, part type, shift, or the like.

Comparison engine 416 may be operative to compare patterns and determine with which known machine operational state or type of manufactured item the pattern is associated. Comparison engine 416 may also be operative to compare the patterns once the machine operational state or type of manufactured item are known, and determine whether the operation of the machine is in line with the determined patterns, or deviates in a manner that requires attention.

Comparison engine 416 may be operative to compare energy consumption patterns of two or more phases to such patterns generated during the training phase. For example, if two or more such patterns demonstrate long-term unexpected power consumption, this may indicate problems with the power supply, general degradation of the machine which may require maintenance, or other phenomena. If only one phase represents unexpected power consumption, this may indicate a problem with a specific module or part. The machine being idle for longer than expected time periods may indicate problems related to operators or to material supply, or the like. It will be appreciated that different measurements, such as current consumption and data that may be received from other systems or sensors such as temperature may be combined, wherein each such measurement may be compared to corresponding measurements, patterns or threshold, and conclusions may be drawn from the combination of the separate comparisons.

Logic module 360 of Application server 148 may comprise alert and recommendation engine 420 adapted to issue alerts when a sampled or calculated value or combination of values exceeds a predetermined threshold or deviates from a predetermined range, as determined by comparison engine 416.

Alert and recommendation engine 420 may further provide focused alerts for certain situations or recommendations for taking actions.

The alerts may include but are not limited to: improper operation of a machine; a failure in a machine; a machine does not receive proper material supply; improper infrastructure such as power supply; improper environmental conditions, loose or unstable electric contact; or the like.

The recommendations may include but are not limited to: a recommendation for a maintenance operation of the machine; a recommendation for a part of the machine that needs replacement or fixing, such as an engine or a bearing; a recommendation for a tool of the machine that needs replacement or fixing such as a blade of a CNC machine; a recommendation for stricter than usual quality assurance of the manufactured item (which quality may degrade due to worn machine tool or part); a recommendation for checking loose or unstable electric contact; a recommendation for checking and fixing the material supply to the machine; a recommendation for checking or fixing the operation of the machine; a recommendation for checking or fixing infrastructure such as power supply or environmental conditions of the machine; a recommendation for replacing equipment or specific tool, or the like.

It will be appreciated that alert and recommendation engine 420 may also operate automatically or in combination with a human operator. For example, alert and recommendation engine 420 may provide an indication to an abnormal situation and the type of abnormality, wherein a user may provide a suggestion.

Alert and recommendation engine 420 may store an indication to the situation and the user's recommendation, and may make the same or similar recommendation should the situation re-appear. In some embodiments, a central repository may be created which may be common to a multiplicity of users, and such recommendations may also be made available to other users. Alternatively, the users may receive periodical updates comprising new such recommendations and the conditions in which the recommendations may become relevant.

It will be appreciated that comparison engine 416 and alert and recommendation engine 420 may be implemented as separate engines or modules, or as a single engine, component or module. Alternatively, certain tasks may be located on either engine, or any other task division between these engines may be used.

Logic module 360 may comprise control and monitoring module 424 for monitoring the proper operation of the system, for example that the sensors are operating at the required sampling rate, that samples are being received by the hub, router, and application server, or the like.

Logic module 360 may comprise management and control flow component 428 for managing the flow of data and control between the various modules and components of the system, I/O management to/from the system, user and permission management, data security, system activation and deactivation, backup, or the like.

Logic module 360 may comprise one or more interfaces to external systems 432, for interfacing to external systems, such as billing systems, other utilities-supplying systems, or the like.

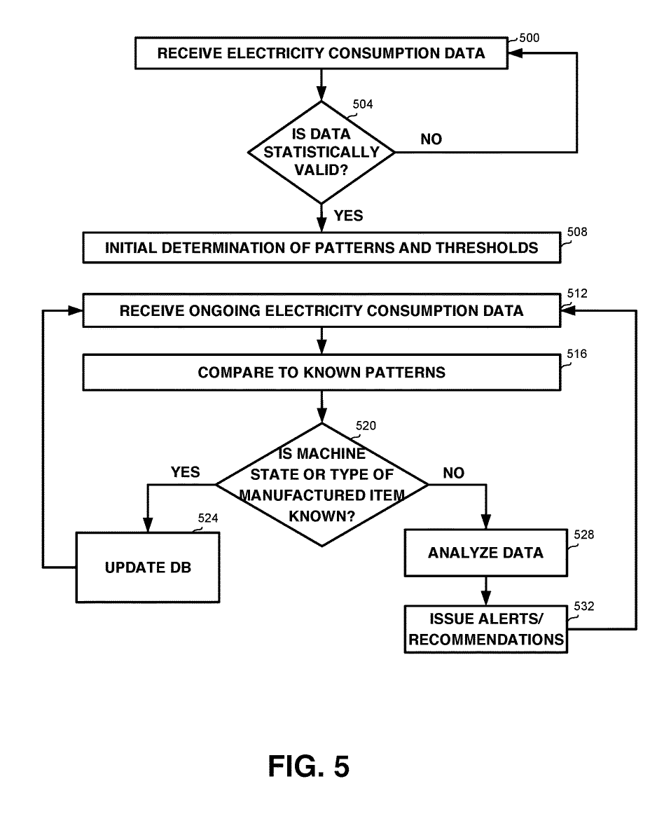

Referring now to FIG. 5, showing an exemplary implementation of a method for analyzing electricity consumption.

On step 500 electricity consumption data may be received. The data may be received over a period of time which is long enough to represent ongoing operation. For example, in a non-seasonal production floor, data may be received during some full operation cycles of all relevant machines, in a seasonal operation data for each season may be received and analyzed separately, or the like.

On step 504 the statistical validity of the data may be assessed, for example whether there is enough data to draw conclusions related to the ongoing operation of the production floor or part thereof. If not enough data is available, or if the data is not representative enough, more data is to be received. The statistical validity may be assessed using tests such as but not limited to T tests, chi-square tests, variance analysis, or the like.

If the data is satisfactory, then on step 508 initial determination or learning of patterns, thresholds or calculations based on the data may be performed, automatically, manually or in combination. Step 508 may further comprise receiving data related to the machine or parts thereof, for example manufacturer data. During step 508, the patterns associated with various machine operational states may be identified, as well as the patterns associated with one or more types of manufactured items.

Steps 500, 504 and 508 may be performed by learning module 408 at an initial learning or training phase of the system, as well as in ongoing learning upon receiving updated data, adding new machines, or the like.

On step 512, which may be performed in an ongoing manner, ongoing electricity consumption data may be received, for example current measurements for one or more, and in particular two or more phases of one or more machines.

On step 516, the received data may be compared to data related to known machines or modules thereof, to determine whether the data relates to a known machine operational state or a type of an item being manufactured. The comparison may be performed by comparison module 416, and may comprise comparing patterns, comparing values to thresholds, comparing calculation results to predetermined results, comparing quantities per time unit to predetermined numbers, or the like.

On step 520 it may be determined whether the data relates to known machine operational state or a type of an item being manufactured, for example by recognizing known patterns.

If in some time period the machine is identified to be in “on” state, but the pattern is not identified as being associated with any of the known item types, then it may be determined that a new type of item is manufactured, and a user may be prompted to indicate the new item type.

If it is determined that if the data relates to a known machine operational state or a type of an item being manufactured, then on step 524 data may be updated and stored in a database, and optionally presented to a user. Such data may include the type or number of manufactured items as assessed or determined from the input data. It will be appreciated that the data may be stored periodically or any time an update is required.

It will be appreciated that the parameters that characterize machine operational states are generally not subject to change significantly over time, therefore a substantial deviation, for example constant current which is higher than expected in standby or idle state, may require triggering an alert. However, the patterns during manufacturing may vary significantly depending on the type of the manufactured item, and an unrecognized pattern may indicate a new such item type.

If the data does not relate to a known machine operational state or a manufactured item, then on step 528, the data may be analyzed, by comparing to past performance of the machine or of similar machines for one or more particular items under similar conditions such as load, environmental conditions, or the like. Comparison may also relate to manufacturer data for the particular machine or part. It may be determined that the machine or part thereof has failed, that the machine does not receive material supply, or the like.

On step 532, an alert or recommendation may be provided by alert and recommendation engine 420. The alert may be provided, possibly depending on its severity by producing a vocal or visual alarm, sending a message, updating a log or a database, or the like.

The disclosed system and method provide for assessing the operation of a production floor according to its electricity consumption.

The system and method may provide for ongoing monitoring of the production floor, for example alerting about acute situations such as excessive current consumption which may indicate overheating of a machine which may damage the machine or cause a fire, frequent current changes or discontinuity which may indicate a loose contact, or the like.

Monitoring also provides for maintaining the ongoing health of the machines, by identifying unexpected behaviors or situations and providing corresponding alerts.

Such monitoring and alerts provide for proper maintenance of the machines, and solving problems as they appear, thus reducing idle times of the machinery and employees, reducing expensive fixing operations, avoiding wasted time and resources, meeting deadlines, keeping the machines in good shape and maintaining their value, or the like.

One example for information that may be obtained and used relates to reducing power consumption. In order to achieve power consumption reduction, distribution of the electricity consumption according to departments, shifts, machines, or the like may be obtained and analyzed. By identifying areas presenting excessive consumption or low efficiency, alerts may be provided in real time, and recommendations may be issued so that equipment may be improved, fixed or replaced, and additional actions may be taken, such as replacing auxiliary equipment, updating protocols, or the like.

Another example relates to avoiding or reducing failures in machines, which may be achieved by ongoing monitoring of the equipment, such as power consumption, total harmonic distortion (THD) or signal to noise ratio (SNR), which indicates power quality of electric power systems, or other factors. Monitoring may also assist in maintaining the infrastructure in a production floor, thus identifying areas that require improvements during establishment and when changes occur, and identifying extraordinary events. Such identification may enable real-time alerts and recommendations for replacing or fixing equipment, installing auxiliary equipment, taking maintenance operations, or the like.

This may enable early identification of failures, thus the issuance of real-time alerts, possible reasons for failures, maintenance recommendations or the like.

For example, in equipment that contains engines such as refrigerators or freezers, pattern deviation may point at the onset of a problem such as a compressor starting to operate before thawing is complete.

Yet another example may relate to preventing fires. By monitoring the power consumption, loose or unstable contact in the electrical grid or in another area of a conductor between the electrical grid and the machine or within the machine may be identified and an alert may be fired, thus preventing fires or other damages. In some embodiments, actions may be taken automatically, such as switching electricity off.

Yet another example may relate to bill distribution, for example billing sub-tenants for the actual consumption rather than by irrelevant parameters such as floor area. In addition the total or partial electrical consumption of a production floor or parts thereof may be assessed and compared to the actual periodical bill to determine its correctness.

Additional examples may relate to CNC machines. One such example relates to identifying the manufactured products and the respective quantities. By monitoring the work plan and the actual work done, alerts may be provided which relate to deviations such as broken or worn machine part or machine tool, irregular raw material, or the like. Actions may then be taken to fix the situation.

The number of items that have been manufactured during a time period may be determined according to the number of cycles the machine went through wherein the cycles comply with the pattern of an item being manufactured. If this number differs significantly from the number of items expected or reported as being to be manufactured, possible sources for the mismatch may be suggested, such as false operator reports, stolen items, or the like. In some embodiments, the number of items may be determined using this analysis, thus making operator or other reports unnecessary.

Another example may relate to distribution of machine operational states, such as off/idle/standby/working. By identifying areas of low efficiency in accordance with machines, machine types, departments, workers, shifts, or the like, conclusions and actions may be determined. Such actions may include determining machines for which the setup time should be changed, departments or workers that need additional guidance or tutoring, improving maintenance by replacing parts or procedures, or the like.

In some examples, a sharp drop in energy consumption before a processing cycle has ended may indicate a break in a tool or a component; continuous rise in electricity consumption may indicate a worn tool or part; instability in electricity consumption may indicate irregularity in the raw material; and a long idle time elapsing between manufacturing different part types may indicate a need to shorten the setup time of the machine.

Yet another example relates to determining from the current consumption how many times setup has been performed for a particular machine, or how many times a specific part or tool has been replaced. The number of setup or parts or tools replacement may further be compared between departments, shifts, or the like.

Yet another example relates to determining from the current consumption whether the setup has been performed properly, for example whether all required steps have been performed and in the right order. In some embodiments, for assessing the setup correctness, the setup may be regarded as another operational state of the machine for which power consumption data at various stages of the setup is collected and compared. Comparison may refer to the setup as a whole or to the measurements taken at any one or more stages.

Yet another example may relate to processing times. By assessing the processing time and energy consumption per each product type, a manufacturing standard or pricing can be determined. The prices and standards may later be updated or enhanced, and deviations may be identified.

Yet another example may relate to times associated with maintenance operations. For example, long time elapsing between failure identification and fixing, or short time between fixing and future failures may indicate that improvement in the service level may be required.

It will be appreciated that some alerts and recommendations may be provided upon experiencing two or more failure indications.

In another example, when an engine behavior is learned, the learned data may refer to mechanical load, operation time, temperature, humidity, or the like, and the learned parameters may include average current consumption, average operation time, wave shape, or the like. The behavior may be learned for about a few hours for given parameters.

The output of the system may include alerts in case of significant deviations from the current consumption values/pattern, operation time or harmonies; comparison between similar units in the organization, comparison to manufacturer data, or the like.

The taken measures may include checking the cause of the problem, such as impaired coils or a mechanical problem, overload, or the like, and taking corrective measures such as maintaining/replacing parts, reducing the load, or the like.

It will also be appreciated that further recommendations may be provided by a human operator in view of symptoms indicated by the system.

It will be appreciated that sampled or measured data may be collected over longer period of time, such that trends may also be identified, such as increments in the current consumption of a machine or a part thereof, or the like. Such trends may indicate a developing problem, an approaching need for maintenance, or the like.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A system comprising:
an application server comprising a processor; and
a non-transitory computer-readable storage medium having stored thereon program instructions that are executable by said processor, for:
(i) in a training stage,
a. receiving electricity consumption data related to at least one phase of power supplied to a particular machine,
b. determining, based on said electricity consumption data, electricity consumption patterns and ranges associated with various operational states of the particular machine and various types of item manufactured by the particular machine, and
c. storing said associated electricity consumption patterns and ranges in a database;
(ii) receiving runtime electricity consumption data related to at least one phase of power supplied to a machine of the same type or of the same model as the particular machine;
(iii) identifying an electricity consumption pattern or range in said runtime electricity consumption data;
(iv) comparing said identified electricity consumption pattern or range with said associated electricity consumption patterns and ranges in the database, to find a match between the identified electricity consumption pattern or range and one of the associated electricity consumption patterns and ranges in the database; and
(v) based on the comparison, determining an operational state of the machine or the type of item manufactured by the machine as one of the different operational states or manufactured items in the database that is associated with said one of the associated electricity consumption patterns and ranges.

2. (canceled)

3. (canceled)

4. (canceled)

5. (canceled)

6. (canceled)

7. The system of claim 1, wherein the program instructions further comprise comparing said identified electricity consumption pattern or range with said associated electricity consumption patterns and ranges in the database, to find a mismatch.

8. (canceled)

9. The system of claim 1, wherein determining the patterns and ranges of electricity consumption of the particular machine associated with various operational states of the particular machine and various manufactured items by the particular machine, comprises automatic detection of said various operational states and said various manufactured items based on a machine-learning algorithm.

10. The system of claim 1, wherein the program instructions further comprise issuing an alert or a recommendation related to maintenance or operation of the machine or the environment.

11. The system of claim 10, wherein the alert is selected from the group consisting of: a failure in the machine; the machine does not receive proper material supply; improper operation of the machine; improper infrastructure such as power supply; loose or unstable electric contact; setup has not been performed properly; and improper environmental conditions.

12. The system of claim 10, wherein the recommendation is selected from the group consisting of: a recommendation for a maintenance operation of the machine; a recommendation for a part of the machine that needs replacement or fixing; a recommendation for a tool of the machine that needs replacement or fixing; a recommendation for checking and fixing the material supply to the machine; a recommendation for stricter than usual quality assurance of a manufactured item; a recommendation for checking or fixing the operation of the machine; a recommendation for checking or fixing infrastructure such as power supply or environmental conditions of the machine; a recommendation for checking for loose or unstable electric contact; a recommendation for notifying maintenance people; a recommendation for updating work plans; a recommendation for directing work to another machine; and a recommendation for replacing equipment.

13. The system of claim 1, wherein the program instructions further comprise monitoring electric supply and operation of the system.

14. A method for analyzing electrical consumption measurements, comprising:
(i) in a training stage,
a. receiving electricity consumption data related to at least one phase of power supplied to a particular machine,
b. determining, based on said electricity consumption data, electricity consumption patterns and ranges associated with various operational states of the particular machine and various types of items manufactured by the particular machine, and
c. storing said associated electricity consumption patterns and ranges in a database;
(ii) receiving runtime electricity consumption data related to at least one phase of power supplied to a machine of the same type or of the same model as the particular machine;
(iii) identifying an electricity consumption pattern or range in said runtime electricity consumption data;
(iv) comparing said identified electricity consumption pattern or range with said associated electricity consumption patterns and ranges in the database, to find a match between the identified electricity consumption pattern or range and one of the associated electricity consumption patterns and ranges in the database; and
(v) based on the comparison, determining an operational state of the machine or the type of item manufactured by the machine as one of the different operational states or manufactured items in the database that is associated with said one of the associated electricity consumption patterns and ranges.

15. The method of claim 14, wherein the step of comparing further comprise comparing said identified electricity consumption pattern or range with said associated electricity consumption patterns and ranges in the database, to find a mismatch.

16. The method of claim 14, wherein the step of determining the patterns and ranges of electricity consumption of the machine related to various operational states of the machine and various manufactured items by the particular machine, comprises automatically detecting said various operational states of the machine and said various manufactured items based on a machine-learning algorithm.

17. (canceled)

18. The method of claim 14, further comprising issuing an alert or a recommendation related to maintenance or operation of the machine or the environment.

19. The method of claim 18, wherein the recommendation is selected from the group consisting of: a recommendation for a maintenance operation of the machine; a recommendation for a part of the machine that needs replacement or fixing; a recommendation for a tool of the machine that needs replacement or fixing; a recommendation for checking and fixing the material supply to the machine; a recommendation for stricter than usual quality assurance of a manufactured item; a recommendation for checking or fixing the operation of the machine; a recommendation for checking or fixing infrastructure such as power supply or environmental conditions of the machine; a recommendation for checking for loose or unstable electric contact; a recommendation for notifying maintenance people, a recommendation for updating work plans, a recommendation for directing work to another machines, and a recommendation for replacing equipment.

20. A computer program product comprising a computer readable storage medium retaining program instructions, which program instructions when read by a processor, cause the processor to perform a method comprising:
(i) in a training stage,
a. receiving electricity consumption data related to at least one phase of power supplied to a particular machine,
b. determining, based on said electricity consumption data, electricity consumption patterns and ranges associated with various operational states of the particular machine and various types of items manufactured by the particular machine, and
c. storing said associated electricity consumption patterns and ranges in a database;
(ii) receiving runtime electricity consumption data related to at least one phase of power supplied to a machine of the same type or of the same model as the particular machine;
(iii) identifying an electricity consumption pattern or range in said runtime electricity consumption data;
(iv) comparing said identified electricity consumption pattern or range with said associated electricity consumption patterns and ranges in the database, to find a match between the identified electricity consumption pattern or range and one of the associated electricity consumption patterns and ranges in the database; and
(v) based on the comparison, determining an operational state of the machine or the type of item manufactured by the machine as one of the different operational states or manufactured items in the database that is associated with said one of the associated electricity consumption patterns and ranges.
